(19) United States
(12) Patent Application Publication
(10) Pub. No.: US 2011/0086235 A1
(43) Pub. Date: Apr. 14, 2011

(54) METHODS OF NUCLEATION CONTROL IN FILM DEPOSITION

(75) Inventor: David Sheel, Ormskirk (GB)

(73) Assignee: STEWART ENGINEERS, INC., Wake Forest, NC (US)

(21) Appl. No.: 12/899,787

(22) Filed: Oct. 7, 2010

Related U.S. Application Data
(60) Provisional application No. 61/249,860, filed on Oct. 8, 2009.

(51) Int. Cl. B32B 9/04; B05D 5/12; C23C 16/40

(52) U.S. Cl. 428/448; 427/58

(57) ABSTRACT

Disclosed herein are methods to achieve a significant degree of nucleation control with a chemical vapor deposition based coating approach, by controlling the chemistry of a specifically chosen under layer on a substrate such as glass and then treating this under layer on at least its surface to a specified degree to achieve targeted nucleation control in the second layer film, which is at least partially crystalline.

### CROSS REFERENCE TO RELATED APPLICATIONS

This application claims priority to U.S. provisional application Ser. No. 61/249,860 filed on Oct. 8, 2009 and incorporated herein in its entirety by reference.

### FIELD OF THE INVENTION

The present invention relates in general to methods of nucleation control in the deposition of thin films in, for example, float baths. In particular, the chemistry of an under-layer is controlled and then treated on its surface to achieve targeted nucleation control.

### BACKGROUND

Chemical Vapor Deposition (CVD) has been widely used for many years across a wide range of industrial applications, to produce thin film coatings. In such a process a reactive gas mixture is introduced in the coating region, and a source of energy applied to initiate (or accelerate) a chemical reaction (usually thermal or plasma), resulting in the growth of a coating on the target substrate.

Atmospheric pressure chemical vapor deposition (APCVD) has established itself increasingly in recent years, as a technologically and commercially attractive sub set of CVD coating. It has been particularly successfully employed in high throughput continuous or semi-continuous coating processes. The APCVD approach has also found application in smaller volume processes where its lower overall costs can be decisive.

Such combinations of advantages has led to APCVD being used in a wide range of industrial applications such a on-line glass coating, tool coating, ion barrier layer deposition, anti-corrosion and adhesion layers on metals, scratch resistant coatings on bottles etc. APCVD is widely used on glass float lines. In many cases, these coatings are deposited in a float bath, where molten glass flows from the glass furnace into a bath of molten tin in a continuous ribbon. The glass, which is highly viscous, and the tin, which is very fluid, do not mix and the contact surface between these two materials is perfectly flat. In such application the benefits of APCVD are due to the integration into the existing glass line giving rise to cost savings and enhanced film properties due to hot fresh glass availability.

In recent years the deposition of functional layers by APCVD has grown significantly. An example of APCVD applied to a continuous process is described in patent no WO 00/705087.

A key aspect of thin film deposition can be nucleation control which can optimize thin film properties significantly. An effective method to achieve such control would be a major benefit.

An example of where such control would be useful is in the manufacture of conductive films such as transparent conductive oxides (TCOs). The electrical properties of the conductive film are strongly influenced by mobility which is linked to film structure and crystallinity. Furthermore, visible scatter is important in products used in, for example, transparent windows. Nucleation control would allow more effective tuning of electrical and/or optical properties as compared with the results currently possible in many processes, including a glass float line.

TCOs are widely used in thin film coatings in such areas as conductive layers in Photovoltaic (PV) stacks and displays and energy efficiency windows (low E and solar control) and window layers. In the PV application area, scatter (across the solar spectrum) can be important, and this is strongly influenced by the film and surface structure. For low E glass, the opposite is normally the case, i.e. minimizing of visible scatter is desirable. For both PV and Low E applications, optimizing conductivity is an important objective. Both surface morphology and electrical conductivity are influenced by material structure which can be affected, in turn, by nucleation.

Fluorine doped tin oxide (FTO) has been the most widely produced TCO by APCVD. It is used in large quantities in energy efficiency windows and also as conductive layers in PVs. In this regard, its attractions include high growth rates, good conductivity and low cost. Furthermore, on-line CVD films such as FTO are known for their hardness, which is a major advantage in subsequent industrial processing and in many of the target applications.

A further key property influenced by nucleation is adhesion. If nucleation is insufficiently controlled, it can lead to reduced adhesion of the thin films to the substrate or to increased susceptibility of such coatings to adhesive initiated failures on aging.

These issues can be most significant in glass line applications of APCVD where the basic glass line conditions (e.g. atmosphere control, speed of substrate, substrate temperature, etc.) are pre-defined to some degree by the glass manufacturing process.

### BRIEF SUMMARY

The embodiments described herein address some or all of the limitations of film structure control by controlling nucleation. The disclosed embodiments are methods of controlling nucleation of a film, and influencing a subsequent growth of the film, by chemical vapor deposition resulting in an at least partially crystalline film. One method disclosed herein comprises the steps of providing a substrate and depositing an under layer on the substrate in a controlled atmosphere. The under layer has at least one of a chemical composition and a physical structure selected to improve nucleation of a thin film subsequently deposited on the under layer compared to nucleation of a thin film deposited directly on the substrate. At least a surface of the under layer is treated with a nucleation control treatment configured to control nucleation of the subsequently deposited thin film. The thin film is then deposited on the treated under layer, resulting in the at least partially crystalline film.

Treating the surface can comprise oxidizing at least the surface of the under layer. The oxidizing can be performed using a gaseous mixture of at least one oxidizing material, such as oxygen. The under layer can comprise silicon, oxygen and carbon at pre-determined levels. For example, the ratios of silicon, oxygen and carbon can be approximately equal. The crystalline film, which is at least partially crystallized, can be a TCO based coating.

These and other embodiments of the invention are described in additional detail hereinafter.

### BRIEF DESCRIPTION OF THE DRAWINGS

The description herein makes reference to the accompanying drawings wherein like reference numerals refer to like parts throughout the several views, and wherein:

FIG. 1 is a flow diagram of a method for controlling nucleation as disclosed herein; and

FIG. 2 is a diagrammatic illustration of deposition in a controlled atmosphere such as that of a glass float bath.

### DETAILED DESCRIPTION

The embodiments herein define processes or methods that are particularly compatible with industrially viable processes for the deposition of coatings, including TCOs. The embodiments are not limited to TCOs and can be extended to any layer in which the effects of nucleation are important to the growth of a film structure.

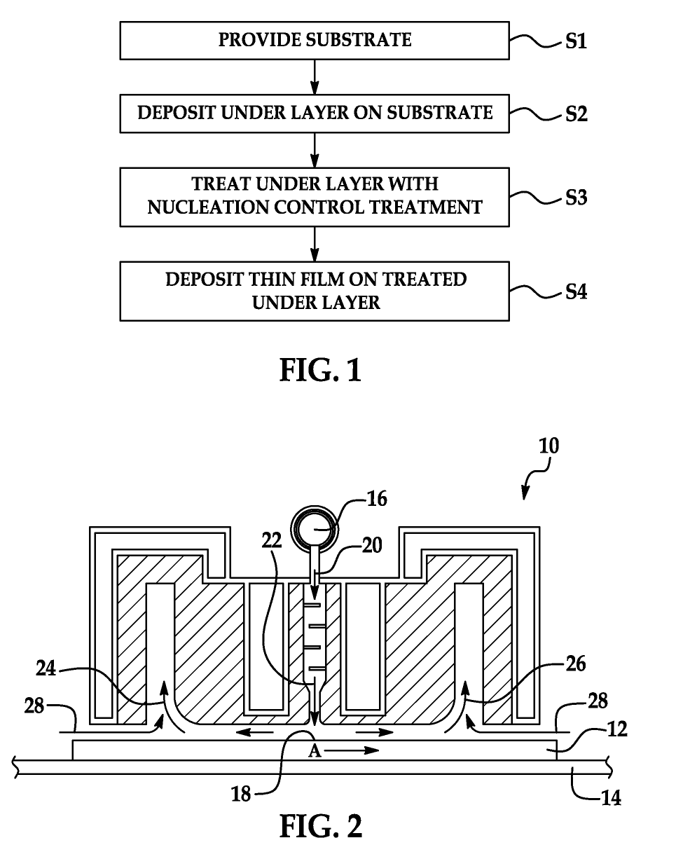

Referring to FIG. 1, a method of controlling nucleation of a film, and influencing a subsequent growth of the film, by chemical vapor deposition resulting in an at least partially crystalline film is illustrated. In step S1, a substrate is provided. In step S2, an under layer is deposited on the substrate. The under layer can have a chemical composition selected to improve nucleation of the second layer that is subsequently deposited on the under layer. The under layer can also or alternatively have a physical structure selected to improve nucleation of the thin film that is subsequently deposited on the under layer, thereby enhancing the film's properties. The under layer thus is selected to be a poor nucleator of the subsequent layer, which provides the control. Poor nucleation of the subsequent layer results in a slower nucleation rate or a nucleation that occurs less densely or less frequently. As used herein, “enhanced properties” are those properties that are improved due to the use of or the nucleation achieved with the use of the under layer as compared to the properties achieved with nucleation of a thin film deposited directly on the substrate without the use of an under layer disclosed herein.

In step S3, at least a surface of the under layer is treated with a nucleation control treatment. The nucleation control treatment performed on the under layer is selected and configured to control nucleation of the subsequently deposited thin film, the deposit of which occurs in step S4. The thin film is then deposited on the treated under layer, resulting in a final film.

The substrate used in step S1 can be any material known to those skilled in the art. For example, the substrate can be a silicon wafer or can be glass, metal or ceramic.

The under layer deposited in step S2 is a non-TCO layer and can be specifically chosen such that it has relatively poor nucleation for the thin film to be grown on top of it. In other words, the under layer is chosen such that it has a lower rate of nucleation. The under layer can be pre-deposited onto the substrate as a barrier to ion diffusion. In the case of glass, for example, glass is a relatively good nucleator for TCOs; however, TCOs that are deposited directly on glass deteriorate over time due to diffusion of the sodium in the glass into the TCO. The under layer can also be pre-deposited on the substrate to influence reflection/transmission properties of the final film stack. For example, the under layer applied under TCOs can be a silica layer containing a controlled degree of carbon. The under layer can be a SiCO type layer having silicon, carbon and oxygen in varying rations. One such SiCO type layer has approximately equal ratios of silicon, carbon and oxygen in the layer. Carbon can reduce the ability of many films, and particularly metal oxides, to grow on top of it. Carbon amounts in the under layer can be varied from less than 1% to over 50% C as an atomic percentage of Si and O. Such films normally exhibit a rough surface, often due to incorporation of particles generated in the gas phase of the CVD process or a bath atmosphere. Controlling the carbon percentage and/or controlling the surface roughness by incorporation of particulate into the under layer can be effectively used to strongly influence nucleation and thereby subsequently deposited thin film structure and functional properties. SiCO type layer is provided by means of example and is not meant to be limiting. It is contemplated that other materials can be used as an under layer depending on the film that is to be applied.

Furthermore, varying the carbon composition of the particles themselves can have a significant further influence on the nucleation properties of the under layer. The particulates can make nucleation occur non-uniformly without further treatment and as noted can be deliberately incorporated to achieve a degree of nucleation control itself which can be combined with the subsequent nucleation control treatment. While not wishing to be limited, it is contemplated that the particulate can act in two ways. First, it has a physical impact on film nucleation, with higher points nucleating different from “valleys”. Second, the particulate can have different chemical compositions due to originating from a different source or reacting in the gas phase differently than on the surface.

The nucleation control treatment in step S3 is selected so that the combination of the intrinsic nucleation properties of the under layer and the subsequently deposited thin film is significantly improved by the treatment. The nucleation control treatments herein provide a previously unseen capability for significant degree of nucleation control, thereby imparting a significant degree of property control on the over-laying thin film or films. The nucleation control treatment can also modify the particles in the under layer. A particular nucleation control treatment can be selected to provide the desired properties in the thin film layer. Properties of the thin film that can be affected by inclusion and treatment of the under layer include nucleation rate, growth rate, thermal stability (important for toughening/annealing), density, diffusion, adhesion, conductivity, scatter, resistance and optical properties, including transmission, reflection and refractive index, as non-limiting examples. As noted, the combination of the chemical composition and/or physical structure of the under layer and the selected nucleation control treatment can provide the desired modified properties in the subsequently deposited film. As a particular example, the combination of the under layer and nucleation control treatment with the subsequently deposited thin film layer can achieve a surface resistivity of less than about 100 Ohms per square. More particularly, the combination and the subsequently deposited thin film layer can have a surface resistivity of less than about 30 Ohms per square.

Since the under layer is not fully oxidized, meaning it has a more “carbon” nature than silica, the subsequent nucleation control treatment is targeted at oxidizing the under layer in a controlled atmosphere. The nucleation control treatment can comprise treating the under layer with a gaseous mixture which contains an oxidizing component or material. Oxidation is particularly effective for overcoming carbon influences, basically oxidizing the SiCO to a more silica-like surface. Non-limiting examples of oxidizing components or material are oxygen, air, nitrous oxide, water vapor, and organic compounds containing oxygen such as alcohols or esters. Other materials for nucleation control treatment are contemplated, such as metal atoms/ions such as tin or titanium from gaseous sources such as chlorides.

After treatment of at least the surface of the under layer with the nucleation control treatment, a second layer is deposited on top of the treated under layer. The properties of this second layer are enhanced due to the inclusion of the treated under layer than if the second layer was deposited directly on the substrate. The second layer is an at least partially crystalline thin film, and can be a conductive film, a TCO such as an FTO, as non-limiting examples. By means of illustration, the precursors typically employed for deposition of a second or thin film layer of FTO can include tin tetrachloride (TTC), dimethyl tin dichloride (DMT) and mono butyl tin trichloride (MBTC). Fluorine sources can be trifluoro-acetic acid (TFAA), nitrogen fluoride (NF3) or hydrogen fluoride (HF) in a gaseous or liquid solution. Accelerants such as water or organic oxygen containing compounds can be added as desired or required.

The method can be performed in a controlled atmosphere, which can include one of a low oxidizing or non-oxidizing atmosphere. The low oxidizing atmosphere and the non-oxidizing atmosphere can be achieved with the use of nitrogen or a hydrogen-nitrogen mixture. The controlled atmosphere maintains the surface condition of the under layer until the second layer has initiated growth, eliminating further chemistry which can occur in the under layer and thereby changing or nullify the nucleation effects. The atmosphere can be controlled from the point the under layer deposition is completed to the deposition of the second layer. The atmosphere can be controlled through out more of the process if desired or required.

It is to be understood that the methods disclosed herein are not limited to a two layer structure. Variations including additional layering in combinations which could be used to achieve the same target objectives are contemplated. For example, step S1 can further include depositing one or more pre-layers on the substrate prior to depositing the under layer. For examples, a pre-layer can be an undoped tin oxide layer, or a tin oxide silica mixed layer.

In addition to or in combination with pre-layers, step S4 can also include the deposition of more than one film layer, for example, depositing a first layer of a first conductive oxide material on the under layer and depositing a second layer of a second conductive oxide material on the first layer. The layers of conductive oxide material can be the same material or different material. Some film layers are deposited with multiple heads, effectively providing a multi-layered structure. The film can be deposited in layers in which the doping concentration changes with depth to provide particular targeted film properties for specialized application.

Methods disclosed herein can be undertaken rapidly and in-situ within a CVD process, and in particular an APCVD process. Other CVD processes can also be employed, such as low pressure CVD, aerosol assisted, direct liquid injection and other processes known to those skilled in the art. APCVD, used for illustration herein, can be undertaken by directing the film forming gas onto and across the surface of the substrate and then extracting it. The gas can be a pre-mixed gaseous mixture delivered through a single head to the substrate surface for each step of the process, or the gases can be delivered using multiple heads by delivering more than one separate gas streams which are mixed close to the substrate surface to minimize any pre-reaction. Both approaches have been widely employed industrially in TCO deposition for many years.

FIG. 2 illustrates a cross section of an APCVD reactor 10 that can carry out the methods herein. For the deposition of the under layer and the film layer, the reactor is typically used in an open system at atmospheric pressure and can employ high gas velocities to achieve short residence times. As seen in FIG. 2, the substrate 12 can be carried by a conveyor or belt 14. Arrow A shows the direction of movement of the substrate 12. The substrate 12 can be a continuous sheet or film carried by the belt 14. A series of individual substrates 12 such as wafers can continuously move along on the belt 14. The series of individual substrates 12 can also move intermittently with the belt 14. Other moving systems known in the art can also be employed.

The zone shown in FIG. 2 uses a single head and is a dual flow reactor, with gas entering in the center and splitting up and down stream. The use of a uni-directional, or single flow, configuration is also contemplated. The reactant gases or precursors 20 are injected at a coating zone from the injector or gas distributor 16 to the surface 18 of the substrate 12. Carrier gases can be used to carry the precursors and are typically nitrogen or air, depending on precursors and process conditions chosen. The gases for the deposition of the layers can be pre-mixed and injected through the same port 22 as shown or they can be delivered through a multiport injector so that the precursor gases are not mixed until they are dispensed in into the deposition region at surface 18 as mentioned above. The latter system is beneficial for highly reactive mixtures. The gases can be delivered to the substrate surface 18 via a temperature controlled distribution head that can allow for controlled gas flow required for achieving film uniformity.

As shown in FIG. 2, the excess reactant gases are exhausted through the gas extraction outlets 24, 26. Inert purge gas 28 can be used to ensure that the reactant gases are contained within the desired regions of the reactor 10 and removed rapidly through the gas extraction outlets 24, 26.

The substrate 12 can be pre-heated to a required temperature before passing under the head or injection port 22. It is also contemplated to move the head 22 across the heated substrate 12 as an alternative approach to moving the substrate under the head 22 in a continuous or intermittent configuration. The under layer and film layer can be deposited in separate coating zones such that the substrate moves on the conveyor from one zone to another. The nucleation control treatment can be carried out in a zone between the coating zones that has the controlled atmosphere. It is also contemplated that the substrate remains stationary while the gases are changed within one coating zone. The changing gases can be injected from different inlet slots which can mean separate heads for each layer or the inlet slots can be integrated in various combination head designs. It is also possible to add additional slots where combinations of target film thicknesses and substrate speeds require this. The steps can be performed with a laminar flow introduced into and through the coating zone to deposit one or more of the under layer, treatment and the film.

The disclosed methods are particularly applicable to a float glass manufacturing line with integral CVD coating installed. A significant degree of nucleation control can be achieved for coatings deposited on a glass float line by controlling the chemistry of a specifically chosen under layer on a glass substrate and then treating the under layer on its surface to a carefully controlled degree to achieve targeted nucleation control. The under layer and film can be deposited on a glass float line in one or more of a float bath, a Lehr gap and in a Lehr.

The examples given below are described in terms of the float line application for clarity of the specific example and its benefits, but generically related benefits are readily understood and available for off-line (i.e. off glass production line) CVD applications also. The following examples are provided for means of illustration and are not meant to limit the scope of the methods disclosed.

The following examples include coating a continuous substrate or film or continuously fed substrates, which move under or through the coating region. The coating is achieved by APCVD.

The following instrumentation can be used for analyzing the resulting films. Scanning electron microscopy (SEM) images were obtained using a Philips XL30 with Phoenix energy dispersive analysis of X-rays (EDAX) spectrometer. X-ray photoelectron spectra (XPS) were recorded on Kratos Axis 165 or Amicus spectrometers while X-ray diffraction (XRD) data was recorded on a Philips PW 1130 diffractometer. Analysis of composition was done by XPS and GDOES (Jobin). Optical properties and haze/scatter were measured on an NKD spectrometer and also on a custom designed collimated light source system to measure angular properties and incorporating an integrating sphere.

Following are the typical experimental conditions applied.

The FTO layers were deposited using a volatile tin precursor (either tin tetrachloride or mono-butyl tin trichloride (MBTC) were employed in this work), and a vaporized fluorine source such as hydrogen fluoride (HF) or trifluoroacetic anhydride (TFAA), and water. The precursors were vaporized by conventional bubbling or flash evaporation techniques and transported along heated lines to the reaction zone. Additional process modifying additives can be included such as alcohols or other organic volatiles. Precursor mixtures were transported in nitrogen with additional oxygen (normally up to 20%) added. The gases were premixed prior to entering the reaction zone and delivered to the substrate by a custom designed CVD head. Deposition was undertaken at a range of substrate temperatures, between about 600 and about 730° C.

### Experiment Example 1

This example deposits an FTO film directly on a glass substrate. As mentioned above and noted in the results, uncoated glass is a relatively good nucleator for TCO but has long term negative effects on the top coat film.

A thin film top coat of FTO approximately 300 nm thick was deposited directly on a glass substrate with 40 Kg/hr MBTC; H₂O at a molar ratio H₂O/MBTC of 1.5; TFAA at a molar ratio MBTC/TFAA of 0.3; and nitrogen as a carrier gas at standard conditions of temperature and pressure (STP) at 70 m³/hr.

The resulting thin film surface resistivity (SR) was 18 ohms per square and the resulting haze was 1.5%. Ohms per square is the unit of an electrical measurement of surface resistivity across any given square area of a material.

### Experiment Example 2

An FTO layer as the thin film is deposited onto an untreated under layer of SiCO results in high haze and low conductivity. A SiCO under layer was deposited on a glass substrate with 0.9 Kg/hr silane, 3.6 Kg/hr ethylene, 3.6 Kg/hr CO₂, and nitrogen as a carrier gas at STP at 4.5 m³/hr.

A thin film top coat of FTO was deposited on the under layer with 40 Kg/hr MBTC; H₂O at a molar ratio H₂O/MBTC of 1.5; TFAA at a molar ratio MBTC/TFAA of 0.3; and nitrogen as a carrier gas at STP at 70 m³/hr.

Results were variable with the thin film SR varying across the substrate from run to run between approximately 40 ohms per square and 150 ohms per square. Haze was also variable from between about 3% and 7%.

### Experiment Example 3

A thin film layer of FTO is deposited on an under layer of silica film with carbon incorporated (SiCO) where the SiCO layer is treated with dry air prior to deposition of the FTO thin film layer. The air flow rate is not critical to make a major change in properties of the top coat. In this example, it was set at approximately 3.0 m³/hr.

The SiCO under layer was deposited on a glass substrate with 0.9 Kg/hr silane, 3.0 Kg/hr ethylene, 3.0 Kg/hr CO₂, and nitrogen as a carrier gas at STP at 8.0 m³/hr.

The thin film top coat of FTO approximately 290 nm thick was deposited with 40 Kg/h MBTC; H₂O at a molar ratio H₂O/MBTC of 3.0; TFAA at a molar ratio MBTC/TFAA of 0.3; and nitrogen as a carrier gas at STP at 70 m³/hr. The resulting SR was between about 25 to 31 ohms per square with a haze of 1.5%.

### Experiment Example 4

A thin film layer of FTO was deposited on a silica under layer with carbon incorporated (SiCO) where the SiCO under layer is treated with dry oxygen/nitrogen mixtures in various concentrations.

The SiCO under layer was deposited on a glass substrate with 1.0 Kg/h silane, 3.0 Kg/hr ethylene, 8.0 Kg/hr CO₂, and nitrogen as a carrier gas at STP at 3.0 m³/hr. The SiCO under layer was treated with an air/N2 mix or O₂/N₂ mix prior to top coat deposition.

A thin film top coat of FTO was deposited with 40 Kg/hr MBTC; H₂O at a molar ratio H₂O/MBTC of 8.0; TFAA at a molar ratio MBTC/TFAA of 0.25; and nitrogen as a carrier gas at STP at 70 m³ hr.

This resulted in the following: a ratio of 1/5 (air/N₂) with an SR of 64 Ohms per square; a ratio of 1/5 (O₂/N₂) with and SR of 50 Ohms per square; and a ratio of 1/4 (O₂/N₂) with an SR of 46 Ohms per square. The conductivity improves as the amount of oxygen increases.

### Experiment Example 5

A thin film layer of FTO was deposited on a silica under layer with carbon incorporated (SiCO) where the SiCO layer is treated with dry air which has water vapor added. Experiment 3 was repeated with the dry air bubbled through a bubbler containing water. Again, enhancement to the SR was observed when compared to examples without surface treatment with water vapor.

### Experiment Example 6

A thin film FTO layer was deposited on a silica under layer with carbon incorporated (SiCO) where the SiCO layer is treated with titanium tetrachloride (TiCl₄) for nucleation and dry air which has water vapor added.

Experiment 3 was repeated where the dry air was bubbled through a bubbler containing titanium chloride. Again, enhancement to the SR was observed when compared to examples without such surface treatment.

While the invention has been described in connection with certain embodiments, it is to be understood that the invention is not to be limited to the disclosed embodiments but, on the contrary, is intended to cover various modifications and equivalent arrangements included within the spirit and scope of the appended claims, which scope is to be accorded the broadest interpretation so as to encompass all such modifications and equivalent structures as is permitted under the law.

What is claimed is:

1. A method of controlling nucleation of a film, and influencing a subsequent growth of the film, by atmospheric pressure chemical vapour deposition resulting in a film having optimized properties, the method comprising the steps of:
providing a substrate;
depositing an under layer on the substrate, wherein the under layer has at least one of a chemical composition and a physical structure selected to improve nucleation of a thin film subsequently deposited on the under layer compared to nucleation of a thin film deposited directly on the substrate;
treating in a controlled atmosphere at least a surface of the under layer with a nucleation control treatment configured to control nucleation of the subsequently deposited thin film; and
depositing a transparent conductive oxide (TCO) layer on the treated under layer, resulting in the film having optimized properties.

2. The method according to claim 1 wherein the under layer comprises silicon, oxygen and carbon at pre-determined levels.

3. The method according to claim 2 wherein the under layer has approximately equal ratios of silicon, oxygen and carbon.

4. The method according to claim 1 wherein the controlled atmosphere is one of a low oxidizing atmosphere and a non-oxidizing atmosphere.

5. The method according to claim 4 wherein one of the low oxidizing atmosphere and the non-oxidizing atmosphere is one of a nitrogen atmosphere and a hydrogen-nitrogen atmosphere.

6. The method according to claim 1 wherein the substrate is glass and the steps are performed in a glass float line.

7. The method according to claim 6, wherein the depositing steps are performed in one or more of the float bath, the Lehr gap and the Lehr.

8. The method according to claim 1 wherein the nucleation control treatment comprises oxidizing at least the surface of the under layer with a gas mixture containing an oxidizing component.

9. The method according to claim 8 wherein the oxidizing component is oxygen.

10. The method according to claim 9, wherein the nucleation control treatment further comprises titanium chloride.

11. The method according to claim 1 wherein the nucleation control treatment is configured to modify one or both of conductivity and scatter in the thin film.

12. The method according to claim 1 wherein the at least one of the chemical composition and the physical structure of the under layer is configured to reduce the nucleation rate of the TCO layer subsequently deposited on the under layer to less than a nucleation rate and density of a TCO layer deposited directly on the substrate.

13. The method according to claim 1 wherein the film having optimized properties has a resistance of less than about 100 Ohms per square.

14. The method according to claim 13 wherein the resistance is less than about 30 Ohms per square.

15. The method according to claim 1 wherein treating at least the surface of the under layer comprises modifying particles in the surface for nucleation.

16. The method according to claim 1 wherein depositing the under layer comprises introducing an under layer feed stream from above the substrate with a laminar flow into and through a first coating zone, and wherein subsequently depositing the TCO layer comprises introducing a TCO feed stream from above the substrate with a laminar flow into and through a second coating zone.

17. The method according to claim 1, wherein depositing the TCO layer comprises:
depositing a first layer of a first conductive oxide material on the under layer; and
depositing a second layer of a second conductive oxide material on the first layer.

18. The method according to claim 1 wherein depositing the under layer comprises:
depositing a first layer of a first material on the substrate; and
depositing a second layer of a second material on the first layer.

19. The method according to claim 1, wherein the substrate moves as one of a continuous sheet, a continuous film, a continuous series of substrates, and an intermittent series of substrates.

20. A film having enhanced properties provided on a substrate, the film comprising:
an under layer provided directly on a surface of the substrate, wherein the under layer comprises silicon, carbon and oxygen that has been treated with an oxidizing component; and
transparent conductive oxide (TCO) layer deposited on the treated under layer.

21. The film of claim 20, wherein the TCO layer comprises mono-butyl tin trichloride and trifluoroacetic anhydride.
